(19) United States
(12) Patent Application Publication
(10) Pub. No.: US 2025/0159955 A1
(43) Pub. Date: May 15, 2025

(54) METHOD FOR MANUFACTURING A QUANTUM ELECTRONIC CIRCUIT WITH A REDUCED GATE PITCH

(71) Applicant: COMMISSARIAT À L’ENERGIE ATOMIQUE ET AUX ENERGIES ALTERNATIVES, PARIS (FR)

(72) Inventor: Heimanu NIEBOJEWSKI, GRENOBLE CEDEX (FR)

(21) Appl. No.: 18/940,183

(22) Filed: Nov. 7, 2024

(30) Foreign Application Priority Data
Nov. 9, 2023 (FR) 2312232

(51) Int. Cl. H01L 29/12; H01L 29/40; H01L 29/423; H01L 29/66

(52) U.S. Cl. CPC H10D 62/814; H10D 48/383; H10D 64/01; H10D 64/015; H10D 64/27

(57) ABSTRACT

A method for manufacturing an electronic circuit includes forming first electrodes distributed at a constant pitch; forming spacers against the first electrodes; forming a second electrode between two neighbouring spacers; and replacing each spacer with a third electrode. The first, second and third electrodes are thus distributed at an average pitch equal to R/4.

### CROSS-REFERENCE TO RELATED APPLICATIONS

This application claims priority to French Patent Application No. 2312232, filed Nov. 9, 2023, the entire content of which is incorporated herein by reference in its entirety.

### FIELD

The technical field of the invention is that of quantum electronics and more particularly the manufacture of such a circuit.

### BACKGROUND

The manipulation of quantum states, also called ‘qubits’ for ‘quantum bits’, offers new possibilities in information manipulation. There are several types of qubit, such as spin qubits, in which the information is stored in the quantum state of a spin. Quantum electronic circuits capable of manipulating spin qubits comprise islands, also referred to as quantum dots, capable of storing qubits while they are being manipulated and measured.

FIG. 1 represents a simplified example of an electronic circuit architecture AA1 as commonly implemented. According to this architecture, the quantum dots AA21 are formed in a semiconductor layer AA11 referred to as the qubit layer. The dots AA21 correspond to wells formed in the electrostatic potential AA20 of the qubit layer AA11 by means of conductive electrodes AA13, referred to as “gate electrodes” or “gates”. The gates AA13 are disposed on the qubit layer AA11 and electrically insulated from the same by a dielectric layer AA12, referred to as the “gate oxide” because it is often formed by an oxide. By modulating electrical potential of the gates AA13, it is possible to modulate shape of the quantum dots AA21. When each dot AA21 comprises a qubit A2, these modulations make it possible to manipulate qubits AA2.

The integration of quantum dots AA21 in the form of an electronic circuit has to satisfy several requirements. On the one hand, a high integration density should be offered in order to provide substantial calculating capacity. Secondly, the methods for manufacturing these quantum electronic circuits have to ensure low circuit variability. Indeed, the efficiency of storage and manipulation of qubits AA2 is highly dependent on the position of qubits within the quantum dots AA21. However, the same can be influenced by their environment.

FIG. 2 considers the circuit of FIG. 1 in which a distribution of electric charges AA14 is dispersed in the qubit layer AA11 and/or the dielectric layer AA12. These electrical charges AA14 correspond, for example, to diluted dopants or vacancies within these layers AA11, AA12. This distribution of charges AA14 modifies electrostatic potential AA20 at the qubit layer AA11 and distorts the quantum dots AA21. Parasitic potential wells AA21′ can be formed, trapping the qubits AA2. The location of qubits AA2 thus becomes erratic rather than vertically aligned with the gates AA13. Manipulation of the qubits AA2 is made more difficult.

In order to reduce the impact of electrical charges AA14 on the location of qubits 2, it is known to reduce spacing between neighbouring gates AA13. Reducing the spacing between these gates AA13 amounts to reducing the pitch between these gates AA13. A gate pitch of less than 80 nm, and preferably less than 25 nm, effectively counters impact of the distribution of electrical charges AA14 on the dots AA21. However, manufacturing an electronic circuit with a greatly reduced gate pitch raises new problems.

The manufacture of gates AA13 with a pitch of less than 25 nm requires, for example, the implementation of Extreme UltraViolet (EUV) lithography steps. This type of lithography requires expensive and complex facilities. In addition, it can give rise to a drift phenomenon when several EUV lithography steps follow one another (referred to as “pitch walking”).

A low gate pitch also complicates alignment of the electrical contacts on each gate. Misalignment or contact protrusion can short-circuit several gates together, making the circuit unusable.

Document US 2019/0140073 A1 describes a method for manufacturing a quantum device from a substrate over which first gates extend. These first gates are distributed parallel to each other and at an initial gate pitch. Second gates are formed between the first gates. The first and second gates are thus distributed with a reduced pitch, equal to half the initial gate pitch. This method thus makes it possible to reduce the final gate pitch of the quantum circuit. However, unless EUV lithography steps are implemented, it is not possible to achieve a final pitch low enough to improve location of the qubits.

### SUMMARY

There is therefore a need to provide an electronic circuit capable of forming quantum dots with reduced width, for example less than 80 nm, and not requiring the implementation of EUV lithography steps for its manufacture.

An aspect of the invention offers a method for manufacturing an electronic circuit making it possible to achieve a final gate pitch divided by four with respect to an initial gate pitch, for example equal to the minimum pitch accessible with DUV (Deep UV)-type lithography equipment. It is thus contemplatable to achieve a final gate pitch of less than 80 nm, or even less than 25 nm, with DUV equipment that conventionally allows a gate pitch of 100 nm to be obtained.

For this, an aspect of the invention relates to a method for manufacturing an electronic circuit from a substrate, comprising the steps of:
forming, on the substrate, first gate electrodes spaced apart from each other, each first gate electrode having a first branch extending parallel to a first direction, the first branches of the first gate electrodes being distributed at a constant pitch R, measured along a second direction perpendicular to the first direction;
forming spacers, against the first gate electrodes;
forming, on the substrate, second gate electrodes, each second gate electrode being disposed between two neighbouring first gate electrodes and separated from each of them by one of the spacers, each second gate electrode having a first branch extending between the two first branches of the neighbouring first gate electrodes; and
forming, as a replacement of the spacers, third gate electrodes, each third gate electrode being disposed between a first gate electrode and second gate electrode which are neighbouring, each third gate electrode having a first branch extending between a first branch of a first gate electrode and a first branch of a second gate electrode.

By “gate electrode”, it is meant a conductive track or a conductive electrode for applying an electrical potential to a semiconductor layer.

By “branch”, it is meant a substantially straight portion of a gate electrode.

By “neighbours», it is meant two nearest neighbour objects. For example, two neighbouring first gate electrodes are spaced apart, adjacent along the second direction and closer neighbours.

By “constant pitch”, it is meant that the pitch is constant to within 10% or even 5%.

By “perpendicular” and ‘perpendicularly’, it is meant perpendicular to within 20° or even 10°. Similarly, by “parallel” and “in parallel to”, it is meant parallel to within 20° or even 10°.

By “forming against a gate electrode”, it is meant forming against opposite sides of said gate electrode.

By “opposite sides”, it is meant two portions of a flank, the flank being a surface extending perpendicularly to the substrate and delimiting an object, such as a gate electrode.

By “spacer”, it is meant an electrically insulating track.

By “against” or “extending against”, it is meant that an object is in direct contact, without an intermediary.

The above method makes it possible to form first electrodes with a predefined pitch, for example to the limit of resolution achievable by DUV lithography equipment. Insertion of the second gate electrodes between each pair of first gate electrodes makes it possible to obtain first and second gate electrodes distributed, along the second direction, at an average pitch of R/2. By inserting third electrodes, instead of spacers, between each pair of consecutive first and second gate electrodes, it is possible to obtain first, second and third gate electrodes distributed at an average final pitch divided by 4 relative to the initial pitch. For an initial pitch of 100 nm, the average final pitch is about 25 nm. This pitch makes it possible to form narrow quantum dots in the active zone which are little, if at all, influenced by charges distributed in the substrate or the active zone.

By “average pitch”, it is meant the average of distances separating two neighbouring electrodes, measured along the second direction, and for each pair of neighbouring electrodes (irrespective of the concept of first, second or third electrode).

In an embodiment, replacing the spacers by the third gate electrodes comprises selectively etching the spacers with respect to the first and second gate electrodes.

In an embodiment, the first gate electrodes are formed from a first sacrificial material, such as polycrystalline silicon; the second gate electrodes are formed from a second conductive material, such as titanium nitride; and the method comprises a step of replacing the first sacrificial material of the first gate electrodes with the second conductive material.

In an embodiment, the first gate electrodes are formed from a first sacrificial material; the second gate electrodes are formed from a second sacrificial material; and the third gate electrodes are formed from a third conductive material; and the method comprises a step of replacing the first and second sacrificial materials of the first and second gate electrodes with the third conductive material.

In an embodiment, each first gate electrode is formed so that the first branch has a first width, measured along the second direction, less than or equal to R/4; and the spacers are formed so as to have a second width, measured along the second direction and at the first branches of the first gate electrodes, less than or equal to R/4.

In an embodiment, each third gate electrode is formed so as to extend between neighbouring first and second gate electrodes and so as to have at least one portion, referred to as a ‘free portion’, extending beyond said neighbouring first and second gate electrodes.

In an embodiment, the method comprises, after forming the spacers and prior to forming the third gate electrodes, partially etching each first gate electrode from one end, etching being carried out selectively with respect to the spacers so that each spacer has a free portion extending beyond the first gate electrodes, forming the second gate electrodes being carried out so that said spacer portions also extend beyond the second gate electrodes and so that when the third gate electrodes are formed, each third gate electrode has, after replacing each spacer, a free portion extending beyond the first and second gate electrodes.

In an embodiment, the method comprises, after forming the third gate electrodes, a step of reconnecting to each free portion of the third gate electrodes extending beyond the first and second gate electrodes.

In an embodiment, forming the first gate electrodes is carried out so that each of the first, second and third gate electrodes also comprises a second branch extending perpendicularly to its first branch.

In other words, the first and second branches of a same first electrode are simultaneously made, for example by etching or deposition through a same mask. Thus, the second and third gate electrodes inserted between the first gate electrodes may also have a second portion extending along the second direction. By virtue of their orientation perpendicular to the first portions (extending in the first direction), the second portions can be freely distributed along the first direction without affecting distribution in the second direction. As a result, these second portions can be distributed relatively far apart to make reconnection easier, reducing the risk of short-circuiting with the third electrodes, without impacting the final pitch in the active zone.

For example, forming the second branches of the first and second gate electrodes is carried out so that, for each first and second gate electrodes, a width of the second branch, measured along the first direction, is strictly greater than a width of the first branch.

In an embodiment, the method comprises reconnecting to the second branch of each first gate electrode and of each second gate electrode.

According to one development, the second branches of the first gate electrodes are distributed at a constant pitch, measured along the first direction, strictly greater than 2×R.

In an embodiment, the method comprises, prior to forming each second gate electrode and/or each third gate electrode, depositing a dielectric layer, referred to as “gate oxide”, onto the substrate between two neighbouring first gate electrodes, the forming of each second gate electrode and/or each third gate electrode being carried out on the gate oxide.

By heel, it is meant a dielectric layer having a substantially constant thickness.

An aspect of the invention also relates to an electronic circuit comprising, on a substrate:
first gate electrodes spaced apart from each other, each first gate electrode having a first branch extending in parallel to a first direction, the first branches of the first gate electrodes being distributed at a constant pitch R, measured along a second direction perpendicular to the first direction;
second gate electrodes, each second gate electrode being disposed between two neighbouring first gate electrodes, each second gate electrode having a first branch extending between the two first branches of the neighbouring first gate electrodes,
   the electronic circuit being remarkable in that it comprises third gate electrodes, each third gate electrode being disposed between a first gate electrode and a second gate electrode which are neighbouring, each third gate electrode having a first branch extending between a first branch of a first gate electrode and a first branch of a second gate electrode, and in that the first, second and third gate electrodes are distributed at an average pitch, measured along the second direction, equal to R/4.

In some embodiments, at least two gate electrodes among the first gate electrodes or at least two gate electrodes among the second gate electrodes or at least two gate electrodes among the third gate electrodes both having a contact independent from one another.

It is then possible to polarize the gates independently from each another.

In an embodiment, the first, second and third gate electrodes at least partly extend over a portion of the substrate, referred to as the “active zone”, configured to accommodate quantum dots.

In an embodiment, the first gate electrodes comprise a first conductive material and the second gate electrodes comprise a second conductive material, identical to the first conductive material.

In an embodiment, the third gate electrodes comprise a third conductive material, identical to the materials of the first and second gate electrodes.

In an embodiment, each third gate electrode has a portion, referred to as the “free portion”, extending beyond the first and second gate electrodes, the electronic circuit comprising electrical contacts, each electrical contact being connected to a free portion of a third gate electrode extending beyond the first and second gate electrodes.

The invention and its different applications will be better understood upon reading the following description and upon examining the accompanying figures.

### BRIEF DESCRIPTION OF THE FIGURES

The figures are set forth by way of indicating and in no way limiting purposes of the invention. Unless otherwise specified, a same element appearing in different figures has a single reference.

FIG. 1 and FIG. 2 show circuits according to prior art.

FIG. 3, FIG. 4 and FIG. 5 set forth a first embodiment of an electronic circuit according to the invention.

FIG. 6 sets forth a second embodiment of an electronic circuit according to the invention.

FIG. 7 sets forth a third embodiment of an electronic circuit according to the invention.

FIG. 8, FIG. 9, FIG. 10, FIG. 11, FIG. 12, FIG. 13, FIG. 14, FIG. 15, FIG. 16, FIG. 17, FIG. 18, FIG. 19, FIG. 20, FIG. 21 set forth intermediate devices obtainable in different steps or sub-steps of a manufacturing method according to the invention.

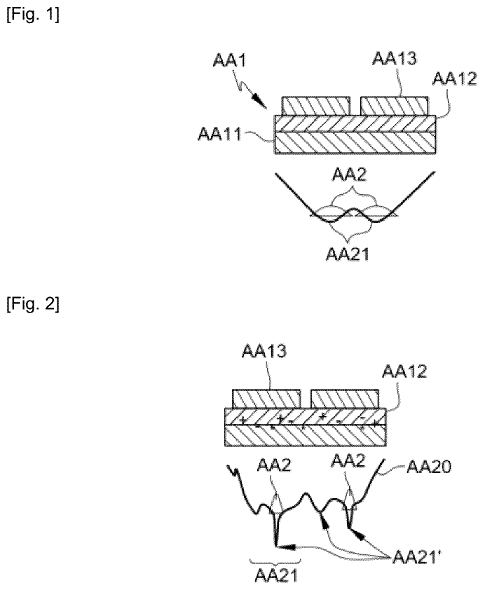

### DETAILED DESCRIPTION

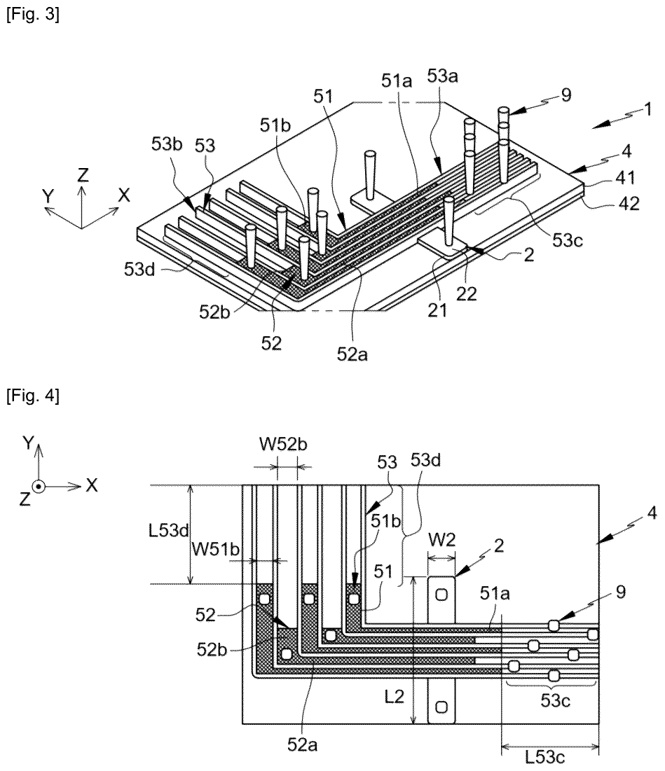

FIGS. 3 and 4 schematically set forth a first embodiment of an electronic circuit 1 according to the invention. FIG. 3 sets forth a perspective view, while FIG. 4 shows a top view of the circuit 1.

The electronic circuit 1 comprises a substrate 4 extending in a {X; Y} plane. The substrate 4 comprises a portion 2 referred to as the “active zone”. The active zone 2 is for accommodating quantum dots and qubits therewithin. It is raised above the substrate 4, also referred to as a “mesa”. The circuit 1 also comprises an array of conductive electrodes 51, 52, 53 referred to as gate electrodes, extending, among other things, over the active zone 2. The gate electrodes 51, 52, 53 are arranged to enable an electrical potential to be applied to the active zone 2 so as to be able to modulate the electrostatic field in the active zone 2 and form quantum dots therein.

The circuit 1 makes it possible to form quantum dots distributed along a single direction (in this case direction Y). Indeed, the active zone 2 has a parallelepiped shape with a very high aspect ratio. Especially, its thickness, measured along direction Z, is very small, from 5 nm to 30 nm. In this embodiment, it also has a width W2, measured along a first direction X, of between 10 nm and 100 nm. On the other hand, it has a length L2, measured along a second direction Y, greater than 100 nm and up to several micrometres. This length L2 depends, among other things, on the number of quantum dots targeted, the size and distribution of the gate electrodes 51, 52 and 53. In this way, quantum dots formed in the active zone 2 are restricted in width (along X) and thickness (along Z). On the other hand, they are distributed along the length of the active zone 2 (along Y).

The gate electrodes 51, 52, 53 extend above the active zone 2, along direction X, overlapping the same. In this way, the electrodes 51, 52, 53 modulate the electrostatic field of the active zone 2 along direction Y form all the quantum dots distributed along direction Y.

The active zone 2 comprises a thin semiconductor layer 21, for receiving quantum dots. This thin layer 21 may be called the qubit layer. In the embodiment of FIGS. 3 and 4, the qubits layer 21 of the active zone 2 corresponds to an extension from a thick semiconductor layer 41 of larger dimension than the substrate 4. This arrangement can be obtained by etching the thick layer 41 of the substrate 4 through a mask so as to retain only the mesa forming the active zone 2. Alternatively, the qubit layer 21 can be cut out into the thick layer 41 by a trench made in the thick layer 41 of the substrate 4.

The active zone 2 also comprises an insulating layer 22 extending over the qubit layer 21. This insulating layer 22 extends between the qubit layer 21 and the conductive electrodes 51, 52, 53 thus forming a so-called “gate oxide” layer. The gate oxide 22 can be formed by oxidising the surface of the qubit layer 21 or by depositing a dielectric onto this layer 21. Alternatively, the gate oxide may be of a nature other than an oxide, however, through misuse of language, it will be called “gate oxide” all the same. The gate oxide 22 may have a thickness, measured along Z, of between 1 nm and 20 nm.

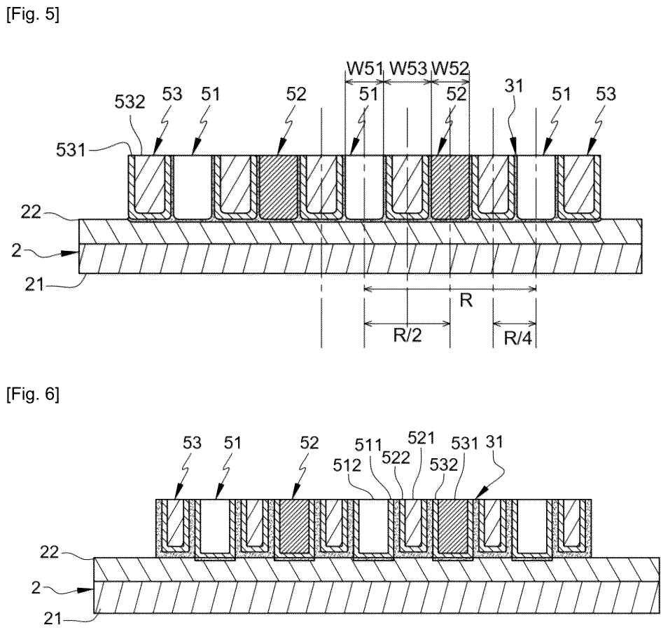

In this embodiment, the gate electrodes 51, 52, 53 have a particular L shape. They thus form two straight branches 51a, 52a, 53a, 51 b, 52b, 53b which are consecutive and perpendicular to each other. A first straight branch 51a, 52a, 53a extends over the active zone 2, along direction X. A second straight branch 51b, 52b, 53b extends at a distance from the active zone 2, along direction Y. The electrodes 51, 52, 53 are arranged side by side and rest on each other, only separated by an insulating layer (discussed below, with reference to FIGS. 5 and 6). The first branches 51a, 52a, 53a extending over the active zone 2 make it possible to apply an electrostatic field to the active zone 2 and form quantum dots in the qubit layer 21. The second branches 51b, 52b, 53b, extending away from the active zone 2 enable these electrodes 51, 52, 53 to be connected.

Herein, each electrode 51, 52, 53 is connected to an electrical contact 9. The contacts 9 are, for example, conductive vias extending perpendicularly to the substrate 4. These contacts 9 are usually connected to the electrodes 51, 52, 53 during a so-called “reconnection” step. For example, a well is formed vertically from each electrode 51, 52, 53 and a contact 9 is formed in said well, in direct contact with one of the electrodes 51, 52, 53.

Contacts 9 are also connected to the active zone 2.

Reconnection can be critical, in part because of the alignment of the wells with respect to the electrodes 51, 52, 53. Slight misalignment or poor control of the diameter of the well can cause a contact 9 on two neighbouring electrodes 51, 52, 53 to overlap. This reconnection step is moreover made more delicate when the pitch between electrodes is small, as is the case in an aspect of the invention.

To alleviate this problem, reconnection to the first and second electrodes 51, 52 is made on the second straight branches 51b, 52b of these electrodes 51, 52. Indeed, the second straight branches 51b, 52b of the first and second electrodes 51, 52 are oriented along the second direction Y. They can be widened and/or spread apart without impact along the first direction X, i.e. on the arrangement of the first straight branches 51a, 51b (in order to maintain an optimum pitch at the active zone 2).

For example, the second straight branches 51b of the first electrodes 51 can be distributed along the first direction X with a constant pitch strictly greater than R (R being the constant pitch along which the first straight branches 51a of these same first electrodes 51 are distributed). In an embodiment, said second straight branches 51b are distributed with a constant pitch greater than 2×R. Thus, the second straight branches 51b, 52b of the first and second electrodes 51, 52 can be widened while leaving sufficient space for inserting the third electrodes 53.

In addition, the widths W51b, W52b of their second straight branches 51b, 52b, measured along X, may be chosen to be sufficiently large to accommodate the contacts 9 without risk of short-circuit with an adjacent third electrode 53.

To make reconnection to the third electrodes 53 easier, without the risk of short-circuiting the neighbouring electrodes 51, 52, each third electrode 53 extends between neighbouring first and second electrodes 51, 52 and beyond these neighbouring first and second electrodes 51, 52. Thus each third electrode 53 has at least one free portion 53c, 53d, forming a fin without any other electrode directly in contact therewith. Thus, despite the narrow width of the third electrodes 53, they can be connected to a contact 9 without risk of short-circuit.

In the example of FIGS. 3 and 4, the third electrodes 53 have two portions 53c, 53d extending beyond the first and second electrodes 51, 52. For example, the first straight branch 53a of each third electrode 53 extends along the first direction X, overlapping the active zone 2 and protruding from the neighbouring first and second electrodes 51, 52. Each third electrode 53 then has a first free portion 53c extending along the first direction X, from an end of a first or second electrode 51, 52. Each first free portion 53c then has a non-zero length L53c, measured along direction X and from an end of a first or second electrode 51, 52.

In FIGS. 3 and 4, the first free portions 53c are connected to the contacts 9.

In the example of FIGS. 3 and 4, each third electrode 53 also has a second free portion 53d extending beyond the first and second electrodes 51, 52. The second straight branch 53b of each third electrode 53 extends along the second direction Y protruding the neighbouring first and second electrodes 51, 52. Each third electrode 53 then has a second free portion 53d extending along the second direction Y, from an end of a first or second electrode 51, 52. Each second free portion 53d then has a non-zero length L53d, measured along direction Y and from an end of a first or second electrode 51, 52.

FIG. 7 shows one embodiment of circuit 1 in which the second free portions 53d are connected to contacts 9.

FIG. 5 schematically shows a cross-section of the electrodes 51, 52, 53 of the circuit 1 of FIGS. 3 and 4, this cross-section being made at the active zone 2 and along direction Y. This cross-section especially shows the arrangement of the first branches of the electrodes 51a, 52a, 53a in the active zone 2.

The electrodes comprise three sub-assemblies 51, 52, 53 of electrodes corresponding to first electrodes 51, second electrodes 52 and third electrodes 53. There are three first electrodes 51 in these examples. There are two second electrodes 52. There are six third electrodes 32. The electrodes 51, 52, 53 extend over the gate oxide 22. The electrodes are alternately disposed side by side. They are separated from each other by an insulating film 31, which may be an oxide film. The insulating film is, for example, between 1 nm and 5 nm thick.

In this embodiment, the first and second electrodes 51, 52 are made of polycrystalline silicon. The third electrodes 53 comprise a layer of metal 531, for example Ti/TiN, lining the cavity in which the electrode 53 is located, and a conductive material 532, for example of W, filling the lined cavity. When the first and second electrodes 51, 52 are made from the same material, they can be used indifferently to form quantum dots in the active zone 2.

Alternatively, the first, second and third electrodes 51, 52, 53 are made from the same material. All the gate electrodes (51, 52, 53) can be used equally well to form the quantum dots in the active zone 2.

The first, second and third electrodes 51, 52, 53 each have a width W51, W52, W53 of between 20 nm and 80 nm in the active zone 2. They are periodically arranged side by side. The first electrodes 51 are arranged at a pitch R (also referred to as period) which, measured in the direction Y, is, in an embodiment, less than or equal to 80 nm. A second electrode 52 and two third electrodes 53 are inserted between two neighbouring first electrodes 51. The resulting final arrangement has a pitch R/4. The final pitch R/4 makes it possible to form quantum dots in the qubit layer 21 with a dimension along Y, which is reduced for example in the order of 20 nm. It is remembered that at this length, electrostatic charges distributed in the qubit layer 21 no longer significantly modify shape of the quantum dots and therefore location of the qubits in the dots. This circuit 1 therefore offers better location of the qubits in the qubit layer 21. It therefore offers better robustness and/or better reproducibility in terms of the operations that can be performed on the qubits.

FIG. 6 schematically shows an alternative to the electrodes 51, 52, 53 represented in FIG. 5. This alternative is indicated along the same sectional plane as FIG. 6, at the active zone 2.

Unlike the embodiment of FIG. 5, the first, second and third electrodes 51, 52, 53 each have a layer of metal 511, 521, 531, for example Ti/TiN, lining the cavity accommodating each electrode 51, 52, 53, and a conductive material 512, 522, 523, for example of W, filling the lined cavity.

The insulating film 31 separating the electrodes 51, 52, 53 also differs in that it has a greater thickness vertically to the third electrodes 53. The third electrodes 53 therefore have a greater distance from the qubit layer 21 than the first and second electrodes 51, 52. This may result from the mode of manufacturing the third electrodes 53, according to which the cavities for accommodating the third electrodes 53 may first be lined with film 31, for example of oxide, before being lined in turn with a Ti/TiN metal layer and filled with W. It may also result from this manufacturing method that the third electrodes 53 have a width W53 less than the width W51, W52 of the first or second electrodes 51, 52. However, this reduction in the width W53 of the third electrodes does not impact the pitch at which the electrodes 51, 52, 53 are distributed.

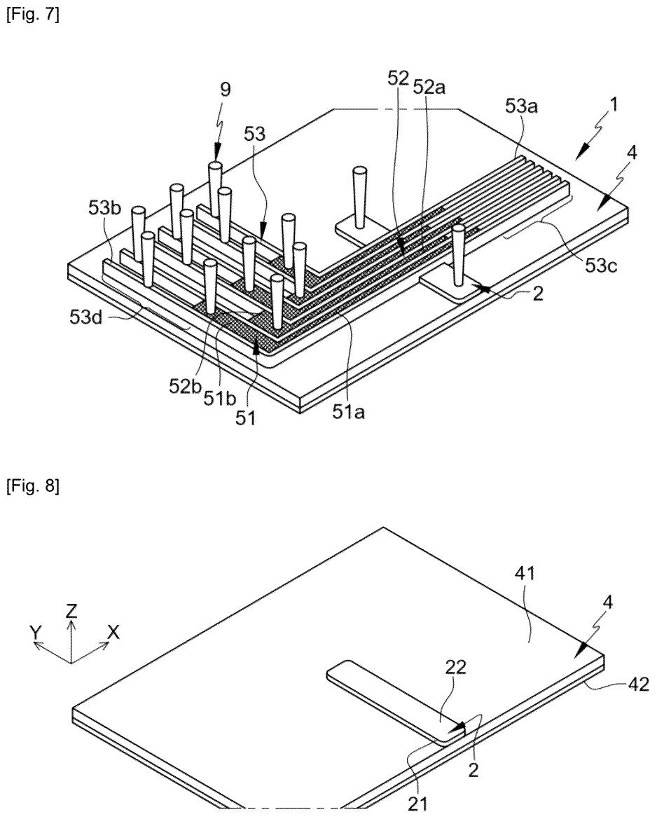

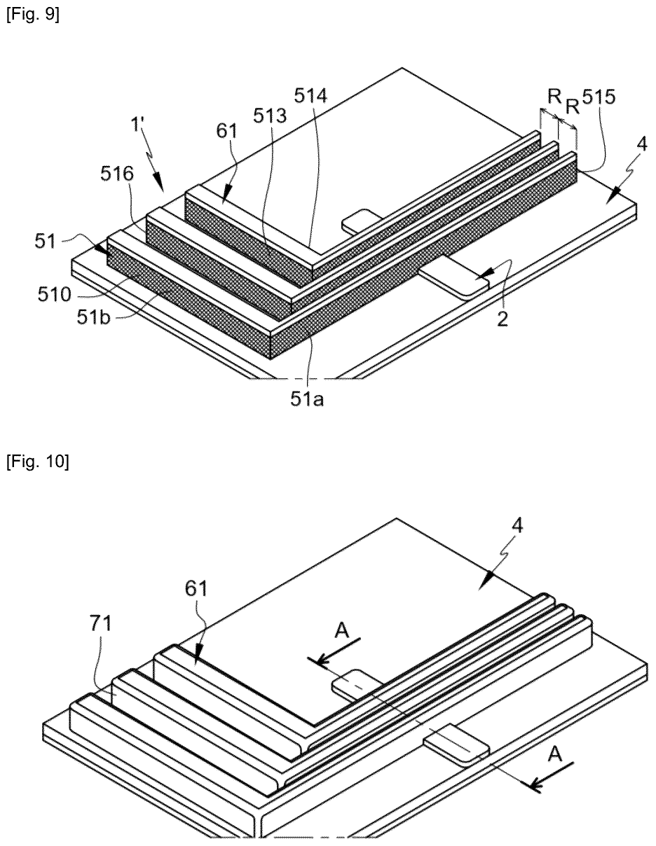

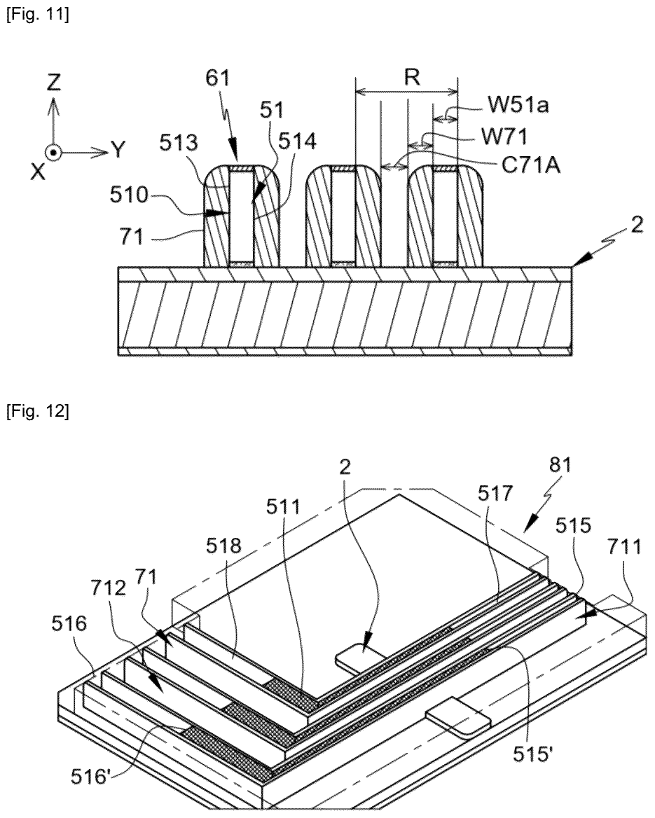

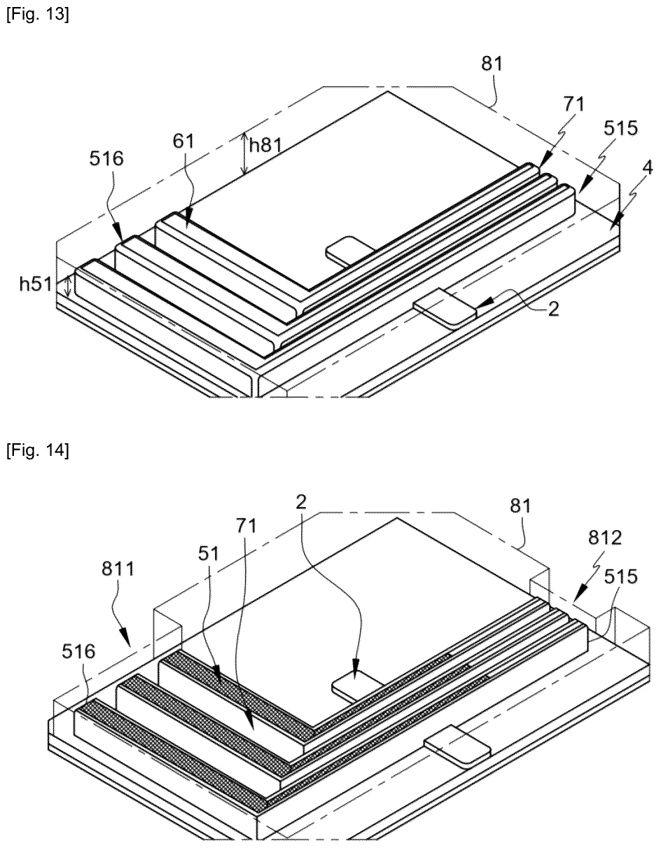

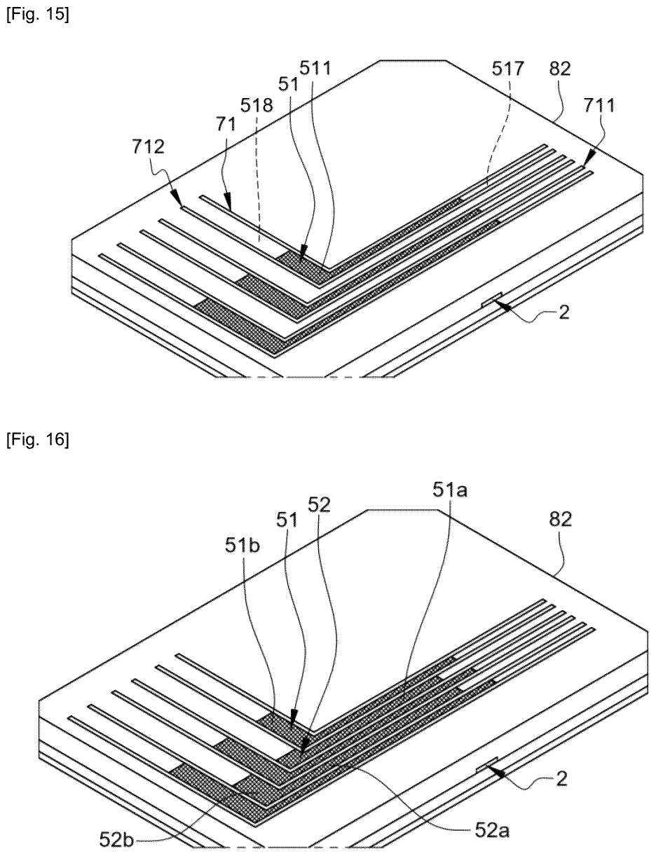

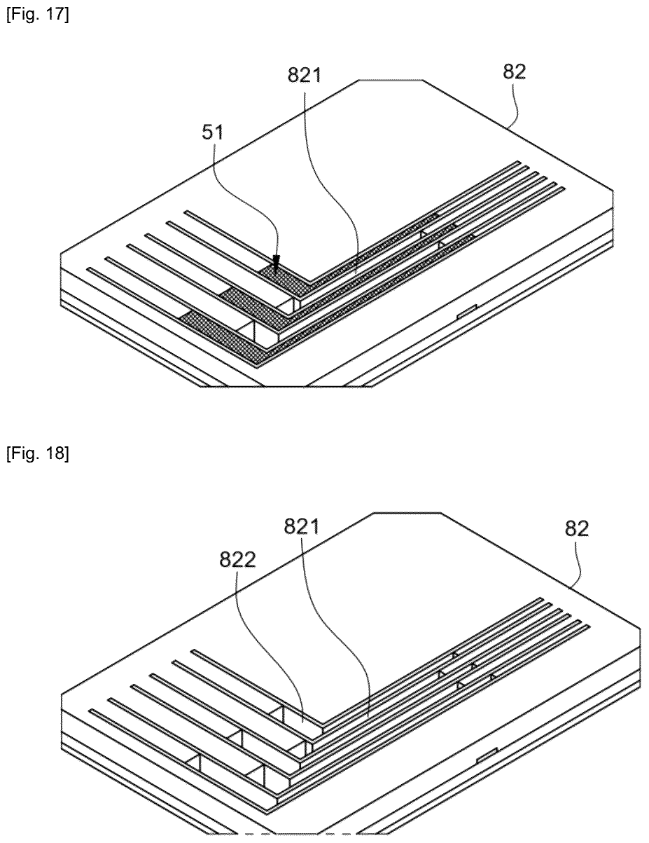

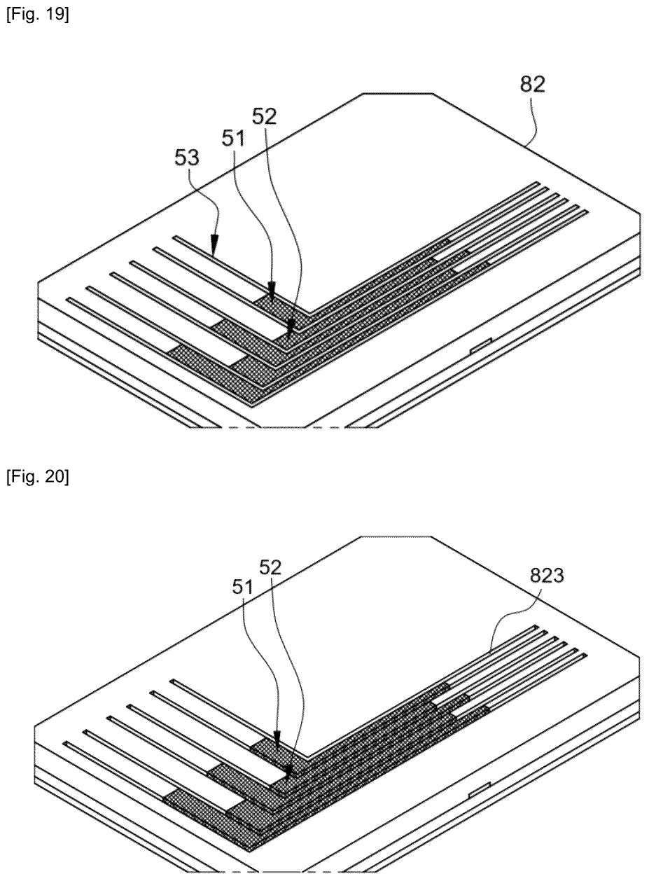

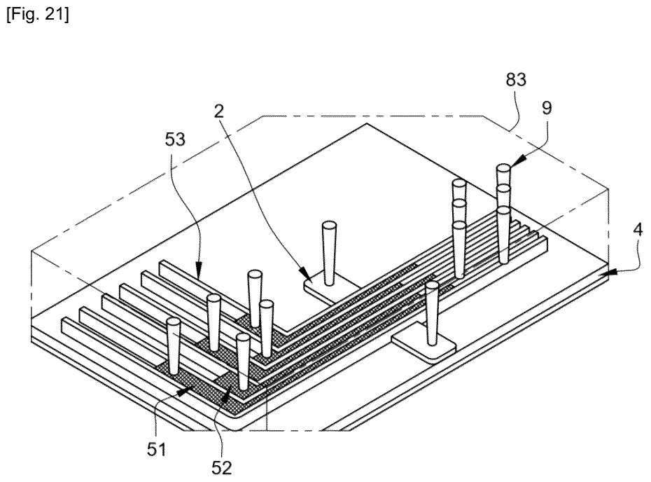

FIGS. 8 to 21 schematically set forth different steps of a method for manufacturing a circuit 1 as set forth in the different embodiments of FIGS. 3 to 7.

FIG. 9 shows the result of a first step of the method of forming the first gate electrodes 51. This step may be preceded by a preliminary step of defining the active zone 2, as illustrated in FIG. 8. This step is carried out from a semiconductor substrate 4. The semiconductor substrate 4 is a bulk substrate, for example made of silicon, or a “SOI” (for ‘Semiconductor On Insulator’) type substrate. In the example of FIG. 8, this is an SOI-type substrate 4 with a thick semiconductor layer 41 made of silicon extending over a buried insulating layer 42, of silicon oxide. The active zone 2 is formed by etching the thick layer 41 through a mask. This etching delimits the qubit layer 21. Etching is carried out, for example, over a thickness of between 5 nm and 30 nm. The gate oxide 22 can then be deposited onto the qubit layer 21 to form the active zone 2.

As previously discussed, the delimitation of the active zone 2 can be achieved by etching a trench in the thick layer 41 rather than completely removing the portion of the substrate 4 that surrounds the active zone 2.

FIG. 9 shows the result of the step aimed at forming the first electrodes 51. The first electrodes 51 extend over the active zone 2. The circuit precursor 1′ as illustrated especially comprises three first electrodes 51. Each first electrode 51 partly extends over the substrate 4 and partly over the active zone 2. They each have two straight branches 51a and 51b, consecutive and arranged perpendicular to each other. A first straight branch 51a partly extends over the active zone 2, substantially perpendicular to a ridge thereof, and a second straight branch 51b extends substantially perpendicular to the first straight branch 51a.

The first electrodes 51 are spaced apart, i.e. there is no direct contact therebetween. In the beneficial mode set forth in FIG. 9, they are also arranged partially parallel to each other. By arranged partially parallel, it is meant that the first straight branches 51a are parallel to each other and the second straight branches 51b are parallel to each other. Stated differently, a first electrode 51 is the image of another first electrode 51 by translation.

Forming the first electrodes 51 can be performed by depositing a layer of a first material covering the substrate 4 and the active zone 2. The layer of first material is etched through a first hard mask 61 deposited onto the first material. The parts of the first material extending under the first hard mask 61 form the first electrodes 51. In an embodiment, deposition of the first hard mask 61 is preceded by chemical mechanical polishing (CMP) so that the first material has a planar surface.

The first material may be a conductive material, if the electrodes 51 are not subsequently removed. It may, for example, be polycrystalline silicon. It may also be a sacrificial material if the first electrodes 51 are removed in order to be redeposited. In both cases, the first material is chosen for its etching speed, which is high compared with that of the hard mask 61. The hard mask 61 is, for example, a silicon oxide SiO₂ or a silicon nitride SiN. Anisotropic etching can be carried out by so-called “dry” etching, i.e. using a plasma, for example argon.

Photolithography of the first hard mask 61 on the layer of first material is carried out considering a pitch R achievable by photolithography equipment. This is desirably the maximum resolution achievable by said equipment, i.e. the smallest achievable pitch. In the case of equipment operating in the deep ultraviolet spectrum (DUV), the pitch R is equal to 80 nm, for example. This pitch R thus makes it possible to form first electrodes 51 which, when they are as close as possible to each other (for example at the active zone 2), are distributed at this pitch R.

The first electrodes 51 are formed with a width W51a at their first straight branches 51a which is less than R/3 and, in an embodiment, less than or equal to R/4. The pitch of the first electrodes 51 at their first straight branches 51a makes it possible to define the final pitch R/4 of the electrodes 51, 52, 53 of the final circuit 1 at the active zone 2 (and therefore of the qubit layer 21). By working at maximum resolution, the final pitch R/4 is guaranteed to be minimal. This results in narrow quantum dots with little or no distortion caused by the electrostatic charges dispersed in the qubit layer 21.

The first electrodes 51 each have a flank 510 which is a side surface delimiting each electrode 51. These flanks 510 are formed upon anisotropically etching the first material and are therefore oriented along the direction of anisotropic etching. This etching is, in an embodiment, carried out at a substantially perpendicular angle to the substrate. Each flank 510 has two portions 513, 514 opposite to each other, in other words two surfaces opposite to each other, forming opposite sides.

By convention, a first electrode 51 has a single flank 510 which completely delimits said electrode 51. In other words, the flank 510 goes all the way around the electrode 51. The opposite sides 513, 514 join the ends 515, 516 of the electrodes 51.

The first electrodes 51 are beneficially formed so as to have a width W51b at their second straight branches 51b which is wider than the width W51a of the first straight branches 51a. Indeed, this widening makes it possible to provide a large surface area for reconnection.

This widening of the second straight branches 51b relative to the first straight branches 51a is made possible by virtue of the substantially perpendicular orientation of the two straight branches 51a, 51b. Thus, the width W51b of the second straight branches 51b, measured along direction X, can be increased without increasing the width W51a of the first straight branches 51a along the direction Y.

FIGS. 10 and 11 show a step for forming layers of dielectric material 71, referred to as ‘spacers’, extending against the opposite sides 513, 514 of the first electrodes 51. FIG. 11 shows a cross-section of FIG. 10 along the plane A-A, perpendicular to the first branches 51a of the first electrodes 51.

To obtain the spacers 71, a layer of dielectric material is for example conformally deposited onto the first electrodes 51 and especially onto the flanks 510 of these electrodes 51. Anisotropic etching is then carried out to delimit the spacers 71. Anisotropic etching is carried out in a direction substantially parallel to the flanks 510. It is stopped when the gate oxide 22 is reached. By virtue of the conformal deposition and anisotropic etching, there remains a layer of dielectric material 71 extending against each opposite side 513, 514. Since etching is stopped when gate oxide 22 is reached, the spacers 71 extending over adjacent electrodes 51 are distinct and spaced apart.

Each spacer 71 has a width W71 (measured from the opposite side 513, 514 on which it is in contact and perpendicular to this side) which is, in an embodiment, constant whatever the branch 51a, 51 b considered of the electrode 51. However, this thickness W71 may be greater at the second branches 51b when these are sufficiently spaced apart. The thickness of the layer of dielectric material conformally deposited defines the width W71 of the spacers 71.

The spacing C71a between two adjacent spacers 71, at the first branches 51a (considering that they are distributed at the pitch R), is equal to C71a=R−2W71−W51a.

In an embodiment, the thickness of the layer of dielectric material conformally deposited to form the spacers is less than R/3. In this way, after the etching step, the spacers 71 have a spacing C71a which allows insertion of the second electrodes 52. Ideally, the thickness of the layer of dielectric material is less than or equal to R/4 so that the spacers 71 have a thickness W71 less than or equal to R/4. The second electrodes 52 thus have, at the first branches 51a of the first electrodes 51, a thickness W52a greater than or equal to R/4.

FIG. 12 shows the result of a step of partially etching the first electrodes 51 from each of their ends 515, 516. Etching is carried out along a direction parallel to the substrate 4 so as to remove sections 517, 518 extending from the ends 515, 516 of the electrodes 51. After etching, the first electrodes 51 have new ends 515′, 516′. Partial etching is carried out selectively with respect to the spacers 71. In this way, each spacer 71 has two portions 711, 712, released from the first electrode 51 on which it rested, forming a fin.

In a subsequent step, the spacers 71 are replaced with conductive electrodes and in particular third electrodes 53 as illustrated in FIGS. 3 to 7. The fins 711, 712 released by etching form the free portions 53c, 53d of the third gate electrodes 53. As a reminder, these free portions 53c, 53d are connected to contacts 9 during a subsequent reconnection step. FIG. 12 shows etching from both ends 515, 516 of the first electrodes 51. However, etching from only one of these ends 515 or 516 may be sufficient to form the free portions 53c or 53d of the third electrodes 53. It is therefore beneficial for etching to be carried out in such a way that the length of one of the sections 517, 518 allows easy reconnection at the free portions 53c, 53d. The length of the section 517, 518 depends on the number of contacts 9 to be positioned and the number of first gate electrodes 51. For example, for three (3) first gate electrodes 51, six (6) contacts 9 may be required (if the contacts 9 are positioned on the same side). The section 517, 518 removed may have a length of at least 300 nm.

FIGS. 13 and 14 set forth two sub-steps for partially etching the first electrodes 51. Etching is especially carried out using the device illustrated in FIGS. 10 and 11, in which the flank 510 of each first electrode 51 is continuously surrounded by a spacer 71, even at two ends 515, 516. Thus, a first sub-step consists in clearing at least one end 515, 516 of the first electrodes 51, for example by severing one of the ends 515, 516. By end, it is meant a portion of the flank 510 which is located, for example, at an apex of the electrode 51.

In order to expose the ends 515, 516, the first electrodes 51, surrounded by their spacers 71, are covered with a first dielectric layer 81, referred to as an encapsulation layer or “PMD layer” (Pre-Metal Dielectric). This is a SiO₂ layer, for example, which can be obtained by plasma deposition. The PMD layer 81 completely covers each electrode 51, each hard mask 61 and each spacer 71. A Chemical-Mechanical Planarisation (CMP) can be carried out while making sure that the thickness h81 of the first PMD layer 81 remains sufficient to allow the aforementioned elements to be covered. A thickness h81 of the PMD layer 81 of 1.5 times the height h51 of the first electrodes 51 is sufficient, for example.

A trench 811, 812 is made starting from the surface of the PMD layer 81 and at each end 515, 516 of the electrodes 51, in order to release the same. In this case, two trenches 811, 812 are made, each disposed vertically to one end 515, 516 of an electrode 51. In other words, the ends 515, 516 of each first electrode 51 are disposed in the volume which is removed to form the trenches 811, 812. The trenches 811, 812 can be made by anisotropic etching, for example through a mask, and stopped at the substrate 4. When etching the trenches 811, 812, the ends 515, 516 of each electrode 51 are also etched. The spacer portions 71 which cover the ends 515, 516 of the electrodes 51 are then also etched, in other words removed, thus releasing the ends of the electrodes 51. A part, for example a small part, of the electrodes 51 may also be removed during etching of the trenches 811, 812. The ends 515, 516 can then be moved back slightly and positioned in vertical alignment with the walls delimiting the trenches 811, 812.

The free ends 811, 812 of the first electrodes 51 expose the first material of each electrode 51 so that it can be removed.

FIG. 12 shows the result when the end sections 517, 518 (extending from the ends 515, 516) are removed from the device of FIG. 14. Removal is achieved, for example, by isotropically etching the electrodes 51 by virtue of the trenches 811, 812 which expose the ends of the electrodes 51 to an etching solution. Thus, etching is carried out in parallel to the surface of the substrate 4, nibbling the electrodes 51 from their ends 515, 516 and towards their centre. The duration and speed of etching determine the length of the section that is removed. It also determines, in a complementary manner, the length of the free portions 53c, 53d.

Said solution is for example tetramethylammonium hydroxide, also referred to as “TMAH”. The etching solution is beneficially chosen to allow selective etching with respect to the spacer material 71 and, in an embodiment, to the hard mask 61.

However, it is desirable that the etching of the end sections 517, 518 does not reach the active zone 2. It is also desirable for the remaining parts of the first electrodes 51 to extend beyond the active zone 2 so as not to induce an edge effect at the active zone 2.

Anisotropic etching of the first electrodes 51 from one end 515, 516 makes it easy to control length of the section removed. It is sufficient to adjust the etching speed and etching time, which are easily controllable parameters. Anisotropic etching from one end also reduces the occurrence of alignment problems. This is because removing the sections by anisotropic etching perpendicular to the substrate requires a step of aligning a mask with the electrodes and spacers, which inevitably leads to an alignment error. This could have a major impact on the length of the fins of the third electrodes, and yield subsequent connection problems during a reconnection step. Control of the length of the sections offered by an aspect of the invention makes it possible to dispense with this type of problem.

FIG. 15 sets forth the device of FIG. 12 in which the end sections 517, 518, after they have been removed, have been replaced by an oxide of the PMD type. The PMD oxide enables the fins 711, 712 of the spacers 71 to be held in place for subsequent manufacturing steps.

This PMD oxide is deposited, for example, after partially removing the first PMD layer 81. Partially removing is for example carried out by CMP with stopping at the hard mask 61 or the first material of the first electrodes 51. A second PMD layer 82 is deposited onto the device so as to completely fill the space left by the end sections 517, 518 removed. This deposition is carried out conformally. The device in FIG. 15 is set forth after further planarisation by CMP to update the spacers 71 and the first electrodes 51 partially etched.

The device of FIG. 16 comprises the second electrodes 52 as set forth in FIGS. 3 to 7. Unlike the device of FIG. 15, the second electrodes 52 are disposed between each pair of adjacent spacers 71.

The first and second electrodes 51, 52 are arranged at a pitch R/2, i.e. half the initial pitch R. This is due to the insertion of the electrodes 52 between the spacers 71.

FIGS. 17 and 18 set forth two intermediate devices obtainable during a first implementation of sub-steps for producing the final first and second electrodes 51, 52 as illustrated in FIG. 16. These two sub-steps take the device of FIG. 15 as an input.

According to the first mode of implementation of the sub-steps for forming the second electrodes 52, first trenches 821 are first formed between pairs of adjacent spacers 71; then the first electrodes 51 are removed leaving free second trenches 822; finally the first and second trenches 821, 822 are filled with a conductive material in order to form the first and second electrodes 51, 52. Filling with the conductive material may be preceded by depositing a conductive film, for example of Ti/TiN, onto the walls of the first and second trenches 821, 822. The conductive material, for example of W, can then be deposited to fill the trenches 821, 822.

When the materials of the first and second electrodes (51, 52) are identical, this makes the electrodes interchangeable with respect to the quantum dots in the qubit layer.

The second mode of implementing the sub-steps to form the second electrodes 52 may be chosen when the first electrodes 51 are formed from a conductive material such as polycrystalline silicon. Unlike the first mode of implementation, there is no need to remove the first electrodes 51. They can be retained. Thus, it is only necessary to form first trenches 821 between adjacent spacers 71; then fill these first trenches 821 with a conductive material or gate structure to form second electrodes 52.

FIG. 17 shows the first trenches 821 diggable in the second PMD layer 82, for example according to the first implementation of the aforementioned sub-steps. These first trenches 821 extend between the first electrodes 51, and in particular between the spacers 71. The first trenches 821 extend at least over the active zone 2 and between the second branches 51b of the first electrodes 51.

In practice, these first trenches 821 can be made by selectively etching the second PMD layer 82 through a hard mask. Etching is performed selectively with respect to the spacers 71 and the first material of the first electrodes 51. In FIG. 17, a mask (not shown) with a rectangular opening is disposed over the first electrodes 51. The opening of the mask is adjusted so as to be vertical to at least part of the two branches 51a, 51b of each first electrode 51 and in particular to its central section 511. The mask opening is also beneficially disposed vertically to the active zone 2. In other words, the projection of the mask opening onto the substrate 4 overlaps the active zone 2. Thus, the second electrodes 52 which will be made will extend over the active zone 2, or even beyond the active zone 2 to reduce edge effects.

The mask opening is also disposed so that the second electrodes 52 all have second branches 52b extending substantially perpendicular to the first branches 52a. In this way, the final electrodes 51, 52 could be connected via a reconnection step.

Etching of the first trenches 821 is carried out by plasma, for example.

FIG. 18 shows the device obtained after forming the first and second trenches 821, 822. The second trenches 822 are obtained, for example, by removing the first electrodes 51. This removal is selectively carried out with respect to the spacers 71. The spacers 71 are thus released and have, on either side, first and second trenches 821, 822 into which a conductive material or a gate structure can be deposited to form the first and second electrodes 51, 52.

Removal of the first electrodes 51, or more particularly the first material, may be achieved by anisotropic etching which is selective with respect to the spacers 71, for example wet etching.

When the first electrodes 51 are separated from the active zone 2 by a dielectric heel, for example made of oxide, the same can also be removed, for example by etching using hydrofluoric acid.

Forming the first and second electrodes 51, 52 is achieved by filling the first and second trenches 821, 822 with a conductive material or a gate structure.

In the case of a conductive material, the same is conformally deposited for example in such a way as to cover the spacers 71. Planarisation by CMP with a stop at the apex of the spacers 71 thus makes it possible to form the first and second electrodes 51, 52 of FIGS. 3 to 7 and 16.

The conductive material is, for example, intrinsically doped polycrystalline silicon.

By gate structure, it is meant a structure having a conductive external envelope, for example of tungsten, for lining the walls of the cavity in which the structure is formed, and a conductive filler material, for example titanium nitride. In the case where the first and second final electrodes 51, 52 have a gate structure, a first conductive material for forming said conductive envelope is conformally deposited so as to line the first and second trenches 821, 822.

The filler material is then deposited so as to cover the whole. Planarisation by CMP with stopping at the apex of the spacers 71 thus makes it possible to form the final electrodes 51, 52.

Since the preceding etching and/or acid cleaning steps may have damaged the gate oxide 22 of the active zone 2, it may be desirable to first form a dielectric material lining at least the bottom of the first and second trenches 821, 822 prior to forming the electrodes 51, 52 in these trenches 821, 822. Thus the qubit layer 21 of the active zone 2 is protected and insulated. The dielectric material is, for example, silicon oxide. The dielectric material can be formed by Atomic Layer Deposition (ALD). Alternatively, it can be formed by oxidising silicon in the qubit layer 21. Said dielectric material has a thickness of about 1 to 5 nm.

Unlike the first aforementioned mode of implementation, in the second mode of implementation for forming the second electrodes 52, only the first trenches 821 are dug, for example in the same way as previously described. The first electrodes 51, when formed by a conductive material, are not removed. In other words, the intermediate device of FIG. 18 is not obtained.

Forming the second electrodes 52 is then achieved by filling the first trenches 821 with a conductive material or a gate structure.

In the case of a conductive material, the same is deposited, for example, in a manner similar to the preceding mode of implementation. When the first electrodes 51 are formed in a conductive material, for example intrinsically doped polycrystalline silicon, and the first trenches 821 are filled with the same conductive material, all the second electrodes 52 are then formed by the same material.

Alternatively, the first trenches 821 may be filled with a different conductive material, thus providing first and second electrodes 51, 52 of two different types.

The same applies when the first trenches 821 are filled with a gate structure as described previously. Again, the first and second electrodes 51, 52 are of two different types.

Since formation of the first trenches 821 and/or acid cleaning of these trenches 821 may have damaged the gate oxide 22 of the active zone 2, a complementary gate oxide may be formed to line the first trenches 821, in the same manner as previously set out (for example by ALD). As a result, the second electrodes 52 will extend over an extra thickness, referred to as a ‘heel’ or ‘wedge’, extending over the qubit layer 21. The thickness of this heel can be adjusted upon depositing the dielectric material (for example, between 3 and 5 nm). This difference in height (in other words, the presence of a heel or not) can make it possible to modify the coupling with the qubit layer 21 in relation to the first electrodes 51, so as to modify function of these gates. A different thickness and/or a different material of the heel from that of the gate oxide makes it possible to adjust the threshold voltage of the electrodes 51, 52, 53.

FIG. 19 sets forth the device obtained after forming the third final electrodes 53. Except for the presence of the contacts 9, this device corresponds to the circuit 1 of FIGS. 3 to 7. In this device, the spacers 71 of FIG. 16 are replaced by the third electrodes 53.

FIG. 20 sets forth a device in which the spacers 71 have been removed. The same have, for example, been etched selectively with respect to the first and second electrodes 51, 52. Etching is carried out isotropically, for example by wet etching. It is, for example, H₃PO₄ if the spacers 71 are of silicon nitride. Removal of the spacers 71 releases third trenches 823.

When the second electrodes 52 are formed while retaining the first electrodes 51, the spacers 71 therefore bear directly against these first electrodes 51 and in particular against the flank 510 of these electrodes. Thus, to avoid direct contact of the third electrodes 53 with these flanks 510, it may be desirable to form an insulating layer in the third trenches 823, lining the same and lining especially the flanks 510 of the first electrodes 51.

The insulating layer may be deposited in the third trenches 823, for example by deposition of a dielectric material by ALD. It may also be formed thermally. For example, when the first and/or second electrodes 51, 52 are formed from a non-metallic conductive material such as polycrystalline silicon, heat treatment of the device of FIG. 20 under oxygen makes it possible to form an oxide film on the flanks 510 of the first and second electrodes 51, 52.

The third electrodes 53 can be formed by depositing a non-metallic conductive material, such as doped polycrystalline silicon. The same is for example conformally deposited until it completely fills the third trenches 823. The third electrodes 53 of FIG. 19 can be formed by CMP planarisation with stopping at the apex of the first and/or second electrodes 51, 52.

Alternatively, the third electrodes 53 can be formed by depositing a metallic material, such as W. For example, a first TiN layer is conformally deposited in the third trenches 823 to line the same. It extends, in an embodiment, over the insulating layer extending against the first and second electrodes 51, 52. A second layer of W is then deposited until the third trenches 823 are completely filled. Finally, the second electrodes 32 are formed by CMP planarisation, with stopping at the apex of the first electrodes 31.

Insertion of the third electrodes 53 between the first and second electrodes 51, 52 makes it possible to distribute the electrodes 51, 52, 53 with an pitch R/4. Thus the electrodes 51, 52, 53 have a reduced pitch on the active zone 2.

FIG. 21 sets forth the device of FIG. 19 which is connected to electrical contacts 9 during a reconnection step. The active zone 2 is also connected.

In order to perform reconnection, an encapsulation is made in a third PMD layer 83. Wells for accommodating the contacts 9 are then made by DUV photolithography and anisotropic etching, for example by plasma. The wells are located, for example, vertically from the second branches 51b, 52b of the first and second electrodes 51, 52 and vertically from the first branches 53a of the third electrodes 53 (as illustrated by FIGS. 3, 4 and 21). Alternatively, the wells can be located vertically from the second branches 53b of the third electrodes 53 (case illustrated by FIG. 7). The contacts 9 are formed, for example, by depositing Ti/TiN followed by filling with W in order to contact all the electrodes 51, 52, 53 manufactured.

1. A method for manufacturing an electronic circuit from a substrate, comprising:
forming, on the substrate, first gate electrodes spaced apart from each other, each first gate electrode having a first branch extending in parallel to a first direction, the first branches of the first gate electrodes being distributed at a constant pitch, measured along a second direction perpendicular to the first direction;
forming spacers against the first gate electrodes;
forming, on the substrate, second gate electrodes, each second gate electrode being disposed between two neighbouring first gate electrodes and separated from each of them by one of the spacers, each second gate electrode having a first branch extending between the two first branches of the neighbouring first gate electrodes; and
forming, as a replacement of the spacers, third gate electrodes, each third gate electrode being disposed between a first gate electrode and second gate electrode which are neighbouring, each third gate electrode having a first branch extending between a first branch of a first gate electrode and a first branch of a second gate electrode.

2. The manufacturing method according to claim 1, wherein replacing the spacers by the third gate electrodes comprises selectively etching the spacers with respect to the first and second gate electrodes.

3. The manufacturing method according to claim 1, wherein:
the first gate electrodes are formed from a first sacrificial material, such as polycrystalline silicon;
the second gate electrodes are formed from a second conductive material, such as titanium nitride, and
the method comprises a step of replacing the first sacrificial material of the first gate electrodes with the second conductive material.

4. The manufacturing method according to claim 1, wherein:
each first gate electrode is formed so that the first branch has a first width, measured along the second direction, less than or equal to R/4; and
the spacers are formed so as to have a second width, measured along the second direction and at the first branches of the first gate electrodes, less than or equal to R/4.

5. The manufacturing method according to claim 1, wherein each third gate electrode is formed so as to extend between neighbouring first and second gate electrodes and so as to have at least one free portion extending beyond said neighbouring first and second gate electrodes.

6. The manufacturing method according to claim 5, comprising, after forming the spacers and prior to forming the second gate electrodes, partially etching each first gate electrode from one end, etching being carried out selectively with respect to the spacers so that each spacer has a free portion extending beyond the first gate electrodes, forming the second gate electrodes being such that said spacer portions also extend beyond the second gate electrodes and so that when the third gate electrodes are formed, each third gate electrode has, after replacing each spacer, a free portion extending beyond the first and second gate electrodes.

7. The manufacturing method according to claim 5, comprising, after forming the third gate electrodes, a step of reconnecting to each free portion of the third gate electrodes extending beyond the first and second gate electrodes.

8. The manufacturing method according to claim 1, wherein, forming the first gate electrodes is carried out so that each of the first, second and third gate electrodes also comprises a second branch extending perpendicularly to its first branch.

9. The manufacturing method according to claim 8, wherein forming the second branches of the first and second gate electrodes is carried out so that, for each of the first and second gate electrodes, a width of the second branch, measured along the first direction, is strictly greater than a width of the first branch.

10. The manufacturing method according to claim 8, comprising reconnecting to the second branch of each first gate electrode and of each second gate electrode.

11. The manufacturing method according to claim 1, comprising, prior to forming each second gate electrode and/or of each third gate electrode, depositing a dielectric layer, forming a gate oxide, onto the substrate between two neighbouring first gate electrodes, the forming of each second gate electrode and/or of each third gate electrode being carried out on the gate oxide.

12. An electronic circuit comprising, on a substrate:
first gate electrodes spaced apart from each other, each first gate electrode having a first branch extending in parallel to a first direction, the first branches of the first gate electrodes being distributed at a constant pitch R, measured along a second direction perpendicular to the first direction;
second gate electrodes, each second gate electrode being disposed between two neighbouring first gate electrodes, each second gate electrode having a first branch extending between the two first branches of the neighbouring first gate electrodes,
third gate electrodes, each third gate electrode being disposed between a first gate electrode and second gate electrode which are neighbouring, each third gate electrode having a first branch extending between a first branch of a first gate electrode and a first branch of a second gate electrode, wherein the first, second and third gate electrodes are distributed at an average pitch, measured along the second direction, equal to R/4, at least two gate electrodes among the first gate electrodes or at least two gate electrodes among the second gate electrodes or at least two gate electrodes among the third gate electrodes both having a contact independent from one another.

13. The electronic circuit according to claim 12, wherein the first, second and third gate electrodes at least partly extend over a portion of the substrate, forming the active zone, configured to accommodate quantum dots.

14. The electronic circuit according to claim 13, wherein the first gate electrodes comprise a first conductive material, the second gate electrodes comprise a second conductive material, identical to the first conductive material, and the third gate electrodes comprise a third conductive material, identical to the materials of the first and second gate electrodes.

15. The electronic circuit according to claim 12, wherein each third gate electrode has a portion, forming the free portion, extending beyond the first and second gate electrodes, the electronic circuit comprising electrical contacts, each electrical contact being connected to a free portion of a third gate electrode extending beyond the first and second gate electrodes.
